(19) United States
(12) Patent Application Publication
(10) Pub. No.: US 2013/0203260 A1
(43) Pub. Date: Aug. 8, 2013

(54) ETCHING METHOD AND ETCHING APPARATUS

(71) Applicants: Kenichi Hara, Nirasaki City (JP); Takashi Hayakawa, Minato-ku (JP)

(72) Inventors: Kenichi Hara, Nirasaki City (JP); Takashi Hayakawa, Minato-ku (JP)

(73) Assignee: TOKYO ELECTRON LIMITED, Tokyo (JP)

(21) Appl. No.: 13/819,382

(22) PCT Filed: Jul. 29, 2011
(86) PCT No.: PCT/JP2011/067398

§ 371 Date: Mar. 27, 2013

(30) Foreign Application Priority Data
Aug. 31, 2010 (JP) 2010-193983

(51) Int. Cl. H01L 21/768; H01L 21/67

(52) U.S. Cl. CPC H01L 21/76886; H01L 21/67069
USPC 438/712; 156/345.3

(57) ABSTRACT

This etching method comprises a step for forming an organic compound gas (22) atmosphere around a copper film (101) that has a mask material (102) formed on the surface thereof and a step for using the mask material (102) as a mask on the copper film (101), irradiating with oxygen ions (6), and performing anisotropic etching of the copper film (101) in the organic compound gas (22) atmosphere.

### TECHNICAL FIELD

The present invention relates to an etching method and an etching apparatus.

### BACKGROUND

A high speed operation of semiconductor devices such as semiconductor integrated circuit devices has recently been progressed. The high speed of operation has been realized by, for example, lowering the resistance of a wiring material. For that reason, instead of aluminum that has been used conventionally, copper having a low resistance than aluminum has been used for the wiring materials.

However, it is difficult to apply the existing dry etching technologies to process copper. This is because that the compound of copper formed while copper is being etched generally has a relatively lower vapor pressure to be evaporated. For example, technologies such as an Ar sputtering and a Cl gas RIE have been attempted, but these technologies were not able to be put to practical use due to the problem such as, for example, the attachment of copper to an inner wall of a chamber. For that reason, copper-based wiring is formed only using a damascene technology. The damascene technology is a technology that forms a trench along a wiring pattern in advance in an interlayer dielectric film, forms a thin copper film to fill the trench, and chemically and mechanically polishes the thin copper film using a CMP method, thereby remaining the copper only inside the trench.

Also, although there is a technology that wet-etches copper with an Iron(□) chloride solution, it is also an isotropic etching.

Patent Document 1 discloses a dry cleaning method using an organic compound gas. Patent Document 1 discloses a technology that etches a thin copper oxide formed on the surface of copper using an organic compound gas.

In Patent Document 1, the copper oxide is etched by using the organic compound gas such as, for example, formic acid gas (HCOOH). The reaction formula is as below.

Cu₂O+2HCOOH→2Cu(HCOO)+H₂O

Cu(HCOO) is volatile.

However, Patent Document 1 concerns to a technology to etch the copper oxide formed on the surface of the copper, and also, the principle of the etching is to etch the entirety of the thin copper oxide isotropically.

### PRIOR ART DOCUMENT

### Patent Document

Patent Document 1: Japanese Patent Laid-Open Publication No. 2009-43975.

### SUMMARY OF INVENTION

As described above, a technology to etch copper isotropically exists, but a technology to etch copper anisotropically is not yet established.

An object of the present invention is to provide an etching method and an etching device which are capable of etching copper anisotropically.

According to a first aspect of the present invention, there is provided an etching method which includes: forming an organic compound gas atmosphere around a copper film that is formed with a mask material on the surface thereof; and performing anisotropic etching of the copper film by irradiating oxygen ions to the copper film using the mask material as a mask under the organic compound gas atmosphere.

According to a second aspect of the present invention, there is provided an etching apparatus that includes: an ion source chamber configured to generate oxygen ions; an accelerating chamber configured to accelerate the generated oxygen ions; an irradiating chamber configured to irradiate the accelerated oxygen ions to a workpiece that includes a copper film and a mask material formed on the copper film; and an organic compound gas source configured to supply an organic compound gas. The etching apparatus is also configured such that the accelerated oxygen ions are irradiated to the workpiece while supplying the organic compound gas to the irradiating chamber.

### BRIEF DESCRIPTION OF THE DRAWINGS

FIG. 1 is a cross-sectional view illustrating an example of an etching apparatus according to an exemplary embodiment of the present invention.

FIG. 2A is a cross-sectional view of a semiconductor wafer for describing the processes of an etching method according to an exemplary embodiment of the present invention.

FIG. 2B is a cross-sectional view of the semiconductor wafer for describing the processes of the etching method according to the exemplary embodiment of the present invention.

FIG. 2C is a cross-sectional view of the semiconductor wafer for describing the processes of the etching method according to the exemplary embodiment of the present invention.

FIG. 2D is a cross-sectional view of the semiconductor wafer for describing the processes of the etching method according to the exemplary embodiment of the present invention.

FIG. 2E is a cross-sectional view of the semiconductor wafer for describing the processes of the etching method according to the exemplary embodiment of the present invention.

FIG. 2F is a cross-sectional view of the semiconductor wafer for describing the processes of the etching method according to the exemplary embodiment of the present invention.

### MODE FOR CARRYING OUT THE INVENTION

Hereinafter, exemplary embodiments of the present invention will be described with reference to the accompanying drawings. Further, common parts are denoted by the common reference numerals through the entire drawings.

### Configuration of Apparatus

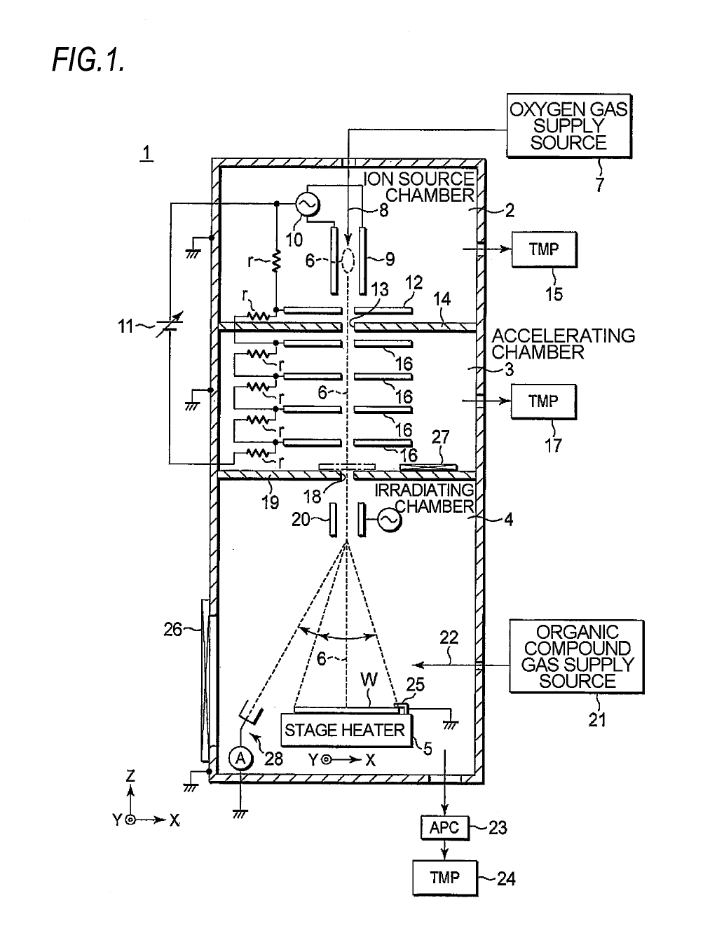

FIG. 1 is a cross-sectional view illustrating an example of an etching apparatus according to an exemplary embodiment of the present invention.

As illustrated in FIG. 1, an etching apparatus 1 is an apparatus that etches a copper film formed on a workpiece anisotropically, and includes an ion source chamber 2, an accelerating chamber 3, and an irradiating chamber 4. The workpiece includes a copper film to be etched and is disposed in irradiating chamber 4 on a stage heater 5 which also serves as a mounting table. An example of the workpiece is a semiconductor wafer W.

Ion source chamber 2 generates oxygen ions 6. Oxygen ions 6 are generated by supplying an oxygen gas 8 from an oxygen gas source 7 to a vessel, for example, a quartz tube 9 capable of being supplied with oxygen gas 8, applying an alternating current field to quartz tube 9 supplied with oxygen gas 8 using an RF power supply 10 to ionize the supplied oxygen gas into, for example, O⁺, O²⁺, O₂⁺, and O₂²⁺. RF power supply 10 becomes a positive potential with respect to a ground potential by an accelerating voltage power supply 11. Oxygen ions 6 are taken out from quartz tube 9 by an extracting electrode 12 which is controlled to have a lower potential than that of RF power supply 10, and are injected into accelerating chamber 3 through a window 14 having a small hole 13.

In addition to the way of generating oxygen ions 6 as described above, oxygen ions 6 may be generated by applying electric current to a filament formed by coating an oxide on tungsten, or a rhenium wire having a low reactivity in a vessel capable of being supplied with oxygen gas 8, and supplying oxygen gas 8 to the vessel such that oxygen gas 8 is ionized on the surface of the filament.

Ion source chamber 2 is maintained in a vacuum state by a pump (TMP) 15 separately from that for any other chamber because it is required to cause oxygen gas 8 to leak out continuously.

An electronic lens 16 is provided in accelerating chamber 3. A hole, where oxygen ions 6 pass, is formed at the central part of an electronic lens 16. Accelerating chamber 3 is maintained in a vacuum state by a pump (TMP) 17 separately from that for ion source chamber 2 and irradiating chamber 4, respectively. Oxygen ions 6 accelerated in accelerating chamber 3 are injected into irradiating chamber 4 through a window 19 provided between accelerating chamber 3 and irradiating chamber 4 and having a small hole 18.

The beam of oxygen ions 6 injected to irradiating chamber 4 is scanned by an electric filed applied to deflecting plates 20 to be irradiated to a desired position on semiconductor wafer W. The beam of oxygen ions 6 may be scanned within the wafer surface under the control of a computer such that oxygen ions 6 have wafer in-plane uniformity.

When the irradiating angle is out of 90 degrees to cause a problem in the anisotropic etching, the beam of oxygen ions 6 is not scanned and stage heater (mounting table) 5 may be horizontally moved in a X-direction and a Y-direction as illustrated by arrow in the figure. For example, stage heater 5 is moved in the horizontal direction while the irradiating angle of beam of oxygen ions 6 with respect to the surface of semiconductor wafer W is maintained at 90 degrees. With this configuration, the etching may be suppressed from being progressed in an inclined direction in relation to the portion of the copper film under the mask material due to the irradiating angle.

An organic compound gas is supplied from an organic compound gas supply source 21 to irradiating chamber 4. An example of the organic compound gas is an organic acid gas 22 containing a carboxylic acid. When the organic compound gas is organic acid gas 22 containing the carboxylic gas, organic compound gas supply source 21 includes a device that evaporates the organic acid containing the carboxylic acid which is a liquid. The pressure within irradiating chamber 4 is adjusted by an automatic pressure controller (APC) 23 and a pump (TMP) 24.

It is expected that when the pressure of organic acid gas 22 within irradiating chamber 4 is high, the speed of anisotropic etching of the copper film is increased. However, since it is believed that in the present example, the oxygen injecting amount by oxygen ions 6 determines the speed of anisotropic etching of the copper film, an excessive pressure is not required for organic acid gas 22 within irradiating chamber 4.

Also, when the pressure of organic acid gas 22 is high, the collision frequency of injected oxygen ions 6 is increased. In this viewpoint, it may be desirable that the pressure of organic acid gas 22 within irradiating chamber 4 is low. The pressure within irradiating chamber 4 may be in a range of 1,000 Pa to 30,000 Pa.

Further, organic acid gas 22 is supplied to irradiating chamber 4. In the present example, window 19 having small hole 18 partitions accelerating chamber 3 and irradiating chamber 4 to cause differential exhaust, so as to prevent organic acid gas 22 from flowing backward to accelerating chamber 3 as much as possible. That is, the pressure within accelerating chamber 3 is set to be higher than the pressure within irradiating chamber 4. As a result, organic acid gas 22 may be prevented from flowing backward to accelerating chamber 3.

Further, oxygen ions 6 irradiated to irradiating chamber 4 may collide with organic acid gas 22. Among the ions generated by the collision of oxygen ions 6 with organic acid gas 22, negative ions leaking into accelerating chamber 3 may be accelerated toward ion source chamber 2 and collide with quartz tube 9 or extracting electrode 12. For that reason, as in this example, when ion source chamber 2 and accelerating chamber 3 are partitioned by window 14 having small hole 13 and accelerating chamber 3 and irradiating chamber 4 are partitioned by window 19 having small hole 18, an advantage may be obtained in that the negative ions are prevented from being moved in a direction opposite to the moving direction of the positive ions.

Further, in a general ion irradiating device, only a specific ion is drawn out from the various ions generated from the inside of quartz tube 9, i.e., the ion source. This is performed by a method of selecting an ion based on a ratio of electrical charge and mass using a Wien filter constituted by a magnetic field and an electrical field.

However, in the present example, it is not necessary to perform a filtering for drawing out only a specific ion. All the generated oxygen ions, that is, O²⁺ and O₂⁺ as well as O⁺ are actively used. This causes the oxide depth of the copper film to have a variation. Since the electric charge of O²⁺ is two times of that of O⁺, the kinetic energy of O²⁺ is two times of that of O⁺, O²⁺ is stopped at a position in the copper film deeper than O⁺, thereby contributing to the oxidation. The mass of O₂⁺ is two times of that of O⁺. Therefore, when O₂⁺ collides with the surface of the copper film to be divided into two pieces, the kinetic energy per each piece is reduced to ½ and is stopped at a position shallower than O⁺, thereby contributing to the oxidation. Since O₂²⁺ has the same ratio of mass/charge as O⁺, it is believed that O₂²⁺ has the same behavior as O⁺. Thus, it is not necessary to remove O₂²⁺.

Since all the generated oxygen ions, that is, not only O⁺ but also O²⁺ or O₂⁺ are irradiated to the copper film as described above, the copper film may be oxidized with a variation, and specially, the copper film may be deeply oxidized in the depth direction. Therefore, an oxidation with good efficiency may be performed.

The temperature of semiconductor wafer W is controlled by stage heater 5. The temperature control by stage heater 5 is not necessary for the oxidation of the copper film. However, for the removal of the copper oxide by the organic acid gas, the temperature of semiconductor wafer W may be maintained in a range of 100□ to 250□ by stage heater 5. The temperature of semiconductor wafer W is controlled as described above, and thus, the reaction of organic acid gas 22 and the copper oxidized by oxygen ions 6 is facilitated. When the organic acid gas containing, for example, a carboxylic acid is, for example, a formic acid gas (HCOOH), the following reaction is facilitated.

Cu₂O+2HCOOH→2Cu(HCOO)+H₂O

Cu(HCOO) is volatile.

Further, since oxygen ions 6 are charged positively, secondary electrons are generated when the oxygen ions collide with the surface of the copper film and the mask material formed on the copper film. As a result, the surfaces of the copper film and the mask material are charged positively. The electrification of the copper film and the mask material generates electrostatic force, thereby repulsing oxygen ions 6 which are positively charged particles. In order to oxidize the copper film anisotropically, it is required to increase the vertical motion of oxygen ions 6 as compared to the horizontal motion thereof. For that reason, it is required to suppress the electrification of the copper film and the mask material. The electrification attenuates the vertical kinetic energy of the oxygen ions.

In addition, when the copper film and the mask material are electrified, it is also considered that the beam of oxygen ions 6 is bent in an abnormal direction when the beam of oxygen ions 6 is scanned by deflection plates 20.

In order to suppress the electrification of the copper film and the mask material, an electrostatic charge elimination mechanism may be installed separately. As an example of an electrostatic charge elimination mechanism, an electrostatic charge elimination electrode 25 with one earthed end may be attached to stage heater 5 to be contacted with the edge of a semiconductor wafer that is formed with a copper film.

### Configuration of Power Supply

Next, the configuration of etching apparatus 1 will be described.

The side wall of ion source chamber 2 may be formed of a member with high strength, for example, a stainless steel or a duralumin, and is electrically earthed for the sake of safety.

RF power supply 10 is connected to a flat electrode provided in ion source chamber 2, to ionize the oxygen gas molecules within quartz tube 9. RF power supply 10 and the flat electrode are maintained at a positive voltage by accelerating voltage power supply 11 with respect to the ground.

Like ion source chamber 2, the side wall of accelerating chamber 3 may be formed of a member with high strength, for example, a stainless steel or a duralumin. The side wall is electrically put to earth for the sake of safety.

An electronic lens 16 is provided in accelerating chamber 3. In the present example, four electronic lenses 16 are provided. Each of electronic lenses 16 lowers the potential thereof gradually toward irradiating chamber 4. In order to realize this, minute electric current is applied between the electrodes of each of electronic lenses 16, using, for example, a high resistance type cement resistor r. With the electrical current flowing through cement resistor r, a potential difference corresponding to an amount of voltage down is produced between the electrodes of each of electronic lenses 16. Therefore, the potential of the electrodes of each of electronic lenses 16 is gradually lowered toward irradiating chamber 4.

Further, electronic lens 16 nearest to ion source chamber 2 is connected to extracting electrode 12 through a cement resistor r, and extracting electrode 12 is also connected to RF power supply 10 through a cement resistor r. As a result, RF power supply 10, extracting electrode 12, and electronic lens 16 nearest to ion source chamber 2 are configured such that the electrical potentials thereof are gradually lowered in this order.

Between the electrodes of each of electronic lenses 16, equipotential surfaces are generated to be parallel to the electrodes, but an equipotential surface sticks out from the inside of the center hole. As a result, emitted oxygen ions 6 are caused to converge by the bent equipotential surface and always pass through the center hole.

The ions accelerated in accelerating chamber 3 pass through small hole 18 of window 19 to be irradiated to irradiating chamber 4.

The side wall of irradiating chamber 4 may also be formed of a member with high strength, for example, a stainless steel or a duralumin, and electrically put to earth for the sake of safety. When the inner wall of irradiating chamber 4 needs to be cleaned for maintenance, it is practical and desirable to coat the inner wall with a chemical-resistant noble metal.

Further, as the side wall of irradiating chamber 4 is earthed, the possibility of introducing the negative ions into accelerating chamber 3 may be decreased. The negative ions are generated due to the collision of oxygen ions 6 and organic acid gas 22.

### Etching Method

Next, an example of an anisotropic etching method of a copper film using etching apparatus 1 will be described.

First, ion source chamber 2 and accelerating chamber 3 are exhausted by pumps 15, 17 and the insides of ion source chamber 2 and accelerating chamber 3 are maintained in a vacuum state.

Next, the ion source is started in advance because a time period is needed from starting to a stable state. That is, oxygen gas 8 is supplied to quartz tube 9, an alternating current field is applied to quartz tube 9 supplied with oxygen gas 8 using RF power supply 10.

Next, a gate valve 26 of irradiating chamber 4 is opened, and a semiconductor wafer W is transported to the inside of irradiating chamber 4 using a transporting device (not illustrated), disposed on stage heater 5, and fixed using a mechanical chuck mechanism (not illustrated). The surface of semiconductor wafer W is provided with a copper film and a mask material. In order to prevent the electrification when irradiating the oxygen ions, electric charge elimination electrode 25 is contacted with the edge of semiconductor wafer W. Then, gate valve 26 is closed, and irradiating chamber 4 is exhausted by pump 24. When the vacuum degree within irradiating chamber 4 becomes a sufficient value, an organic compound gas, which is organic acid gas 22 in this example, is generated by organic compound gas supply source 21 and supplied into irradiating chamber 4.

Up to now, the beam of oxygen ions 6 may be blocked by blocking small hole 18 provided in window 19 using a valve 27, or the beam of oxygen ions 16 may be deflected to the outside of semiconductor wafer W by applying a sufficient voltage to deflecting plates 20. When a beam current meter 28 is provided in the deflected position, the amount and stability of the beam current may be measured.

Now, an anisotropic etching of the copper film will be described. Next, the anisotropic etching of the copper film will be described with reference to examples of cross-sections of the semiconductor wafer.

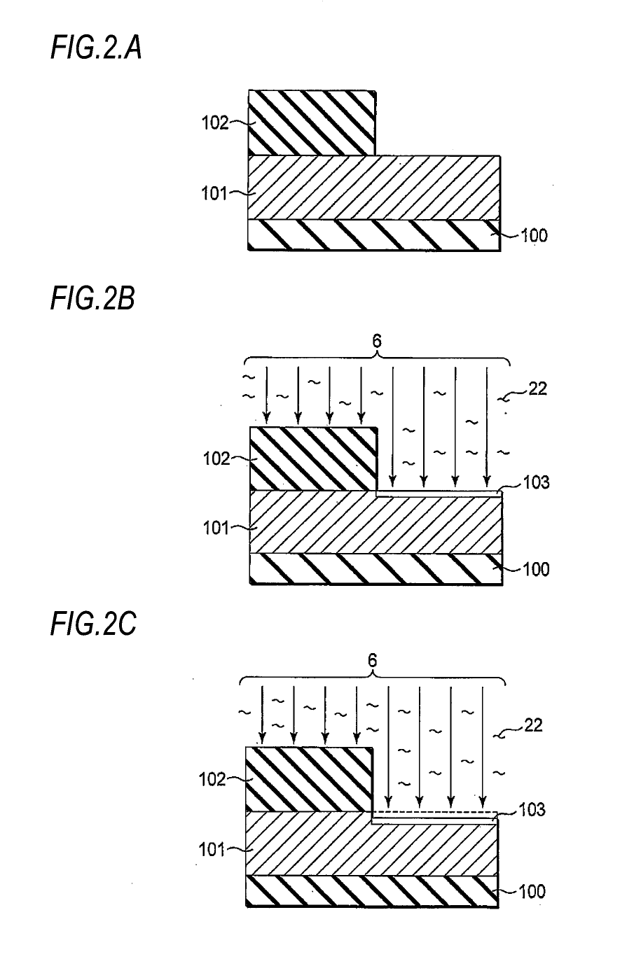

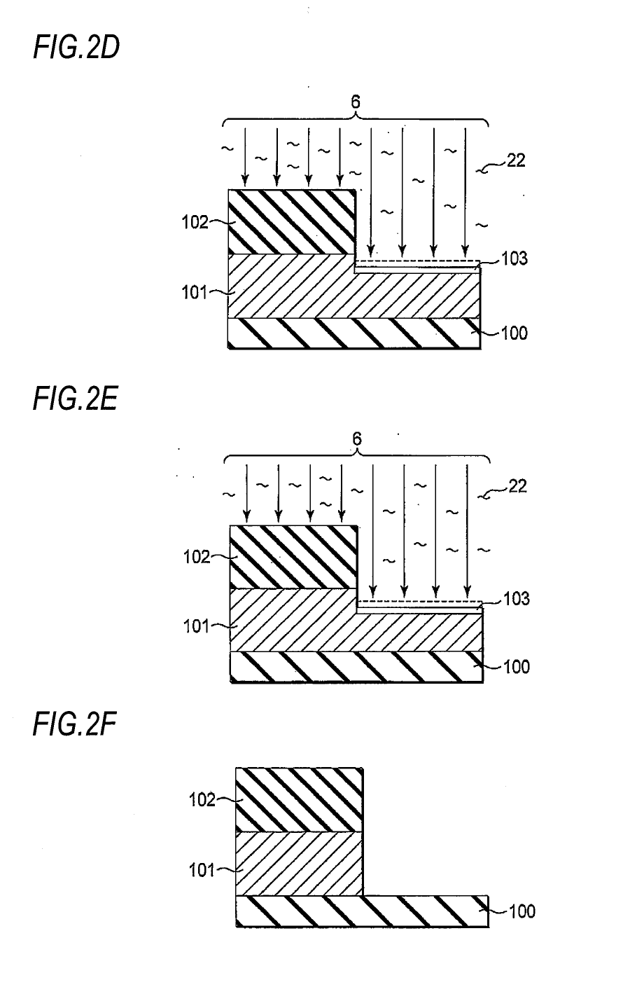

FIGS. 2A to 2F are cross-sectional views illustrating a part of the semiconductor wafer in an enlarged scale for describing the processes of the anisotropic etching method of the copper film as described above.

FIG. 2A illustrates a cross-section illustrating a part of semiconductor wafer W transported into irradiating chamber 4 in an enlarged scale. As illustrated in FIG. 2A, a barrier metal film 100 that prevents the diffusion of copper is formed on semiconductor wafer W, and a copper film 101 is formed on barrier metal film 100. A mask material 102 is formed on copper film 101.

Mask material 102 serves to block oxygen ions 6 such that oxygen ions 6 do not reach copper film 101. For that reason, mask material 102 is required to have a heavy atomic weight and to be thick. If possible, a material having an atomic weight that is larger than that of copper (Cu) (atomic weight: 63.546) and high density is desirable. The film thickness of mask material 102 is set to a thickness such that oxygen ions 6 do not reach copper film 101. The film thickness of mask material 102 may be reduced as the atomic weight of the material is large and the density of the material is high.

Next, the beam of oxygen ions 6 are scanned on semiconductor wafer W by controlling the voltage applied to deflecting plates 20 while supplying organic acid gas 22 into irradiating chamber 4. The injecting angle of oxygen ions 6 is determined by deflecting plates 20 and the irradiating position. For that reason, a sufficient distance is needed between deflecting plates 20 and semiconductor wafer W.

FIGS. 2B to 2E illustrate the appearances of copper film 101 changed as oxygen ions 6 are irradiated to copper film 101 under the organic acid gas 22 atmosphere.

As illustrated in FIG. 2B, the surface portion of copper film 101 to which oxygen ions 6 are irradiated is oxidized and turned into copper oxide 103. However, since the surrounding atmosphere is organic acid gas 22, for example, formic acid gas, copper oxide 103 formed on the surface portion is instantly turned into Cu(HCCO) and H₂O and sublimated, as illustrated in FIG. 2C.

Since copper oxide 103 is sublimated, a copper is exposed in the surface portion of copper film 101. However, since oxygen ions 6 are continuously irradiated, the surface portion is turned into copper oxide 103 again, as illustrated in FIG. 2D. However, since the surrounding atmosphere is organic acid gas 22 continuously, copper oxide 103 formed in the surface portion is instantly turned into Cu(HCCO) and H₂O and sublimated again, as illustrated in FIG. 2E.

Such a phenomenon is continuously generated under the organic acid gas 22 atmosphere while oxygen ions 6 are being continuously irradiated. With the phenomena, finally, copper film 101 is etched anisotropically, as illustrated in FIG. 2F.

Further, in order to decrease the damage of barrier metal film 100, the accelerating voltage may be weakened just before the anisotropic etching of copper film 101 is completed.

As described above, according to the exemplary embodiment, the copper may be etched anisotropically. The exemplary embodiment as described above is effective in a technology to form a copper wiring, and may be used in the applications as follows.
Cu wiring forming processes of a semiconductor integrated circuit device
Bumps and wirings in a 3D process to bond a wafer to another wafer

### Other Application

Although the present invention has been described above with reference to an exemplary embodiment, the present invention is not limited to the exemplary embodiment, and various modifications may be made. For example, in the above embodiment, a description was made as to an example that uses, an organic acid gas, in particular, formic acid gas is used as the organic compound gas. However, the organic compound gas is not limited to the formic acid gas, and besides the formic acid gas, the following organic compound gases may be used.

### Other Organic Compound Gases Applicable to the Present Invention

As an example of the other organic compound gas, a carboxylic acid including carboxylic-group (—COOH) may be used.

As an example of the carboxylic acid, a carboxylic acid expressed by a general formula as follows may be used.

R⁶—COOH

(R⁶ is hydrogen or a straight chain or branched chain type alkyl group or alkenyl group of C₁ to C₂₀, preferably methyl, ethyl, propyl, butyl, pentyl or hexyl)

The examples of the carboxyl acid expressed by the above general formula may include: formic acid (HCOOH), acetic acid (CH₃COOH), propionic acid (CH₃CH₂COOH), butyric acid (CH₃(CH₂)₂COOH), and valeric acid (CH₃(CH₂)₃COOH).

### DESCRIPTION OF SYMBOLS

6 . . . Oxygen ions
22 . . . Organic acid gas
101 . . . Copper film
102 . . . Mask material

1. An etching method comprising:
forming an organic compound gas atmosphere around a copper film that is formed with a mask material on the surface thereof; and
performing anisotropic etching of the copper film by irradiating accelerated oxygen ions to the copper film using the mask material under the organic compound gas atmosphere.

2. The etching method of claim 1, wherein the oxygen ions include an ion having a molecular weight that is not more than O₂.

3. The etching method of claim 1, wherein the organic compound gas is carboxylic acid having carboxylic group (—COOH).

4. The etching method of claim 3, wherein the carboxylic acid is expressed as formula (1) as below.
R—COOH (1)
R is hydrogen, or a straight chain or branched chain type alkyl group or alkenyl group of C₁ to C₂₀)

5. An etching apparatus comprising:
an ion source chamber configured to generate oxygen ions;
an accelerating chamber configured to accelerate the generated oxygen ions;
an irradiating chamber in which a workpiece that includes a copper film and a mask material formed on the copper film is disposed therein and configured to irradiate the accelerated oxygen ions to the workpiece; and
an organic compound gas supply source configured to supply organic compound gas to the irradiating chamber,
wherein the accelerated oxygen ions are irradiated to the workpiece while the organic compound gas is supplied to the irradiating chamber.

6. The etching apparatus of claim 5, wherein the accelerating chamber and the irradiating chamber are partitioned by a window having a hole.

7. The etching apparatus of claim 5, wherein the pressure of the accelerating chamber is higher than the pressure of the irradiating chamber while the accelerated oxygen ions are being irradiated to the workpiece.

8. The etching apparatus of claim 5, further comprising a mounting table on which the workpiece is disposed,
wherein the mounting table further includes an electrostatic charge elimination mechanism configured to eliminate electrostatic charges from the copper film and the mask material formed on the copper film from being charged while the accelerated oxygen ions are being irradiated to the workpiece.
